(19) United States
(12) Patent Application Publication
(10) Pub. No.: US 2023/0284490 A1
(43) Pub. Date: Sep. 7, 2023

(54) DISPLAY DEVICE

(71) Applicant: Samsung Display Co., LTD., Yongin-si (KR)

(72) Inventor: SOOHONG CHEON, Seoul (KR)

(73) Assignee: Samsung Display Co., LTD., Yongin-si (KR)

(21) Appl. No.: 18/090,705

(22) Filed: Dec. 29, 2022

(30) Foreign Application Priority Data
Mar. 4, 2022 (KR) 10-2022-0027901

(51) Int. Cl. H10K 59/131

(52) U.S. Cl. CPC H01L 27/3276; H01L 27/3262

(57) ABSTRACT

A display device includes a substrate, a sub-pixel including a transistor including an active pattern disposed on the substrate and a gate electrode disposed on the active pattern and defining a channel area in an area overlapping the active pattern, and a light emitting element disposed on the transistor, a sensing signal line disposed on the gate electrode to overlap the channel area and that transmits a sensing signal to the gate electrode, a source line extending in a first direction, electrically connected to the active pattern, and that transmits an initialization voltage to the active pattern, and a symmetric sub-pixel having a same structure as the sub-pixel, adjacent to the sub-pixel in a second direction intersecting the first direction, and symmetrical to the sub-pixel with respect to an imaginary symmetric line passing through a center of the source line.

### CROSS-REFERENCE TO RELATED APPLICATION(S)

This application claims priority to and benefits of Korean Patent Application No. 10-2022-0027901 under 35 U.S.C. § 119, filed on Mar. 4, 2022 in the Korean Intellectual Property Office, the entire contents of which are hereby incorporated by reference.

### BACKGROUND

### 1. Technical Field

Embodiments relate to a display device that provides visual information.

### 2. Description of the Related Art

With the development of information technology, the importance of a display device, which may be a connecting medium between a user and information, is being emphasized. For example, the use of display devices such as a liquid crystal display device (LCD), organic light emitting display device (OLED), plasma display device (PDP), quantum dot display device, and the like is increasing.

The number of components included in the display device is increasing to improve performance. However, miniaturization of the display device can be achieved in case that the components may be arranged within a limited area. Accordingly, there is a need for a method for improving the efficiency of an area of the display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides a display device with improved display quality.

A display device according to embodiments of the disclosure may include a substrate, a sub-pixel including a transistor including an active pattern disposed on the substrate and a gate electrode disposed on the active pattern and defining a channel area in an area overlapping the active pattern, and a light emitting element disposed on the transistor, a sensing signal line disposed on the gate electrode to overlap the channel area and that transmits a sensing signal to the gate electrode, a source line extending in a first direction, electrically connected to the active pattern, and that transmits an initialization voltage to the active pattern, and a symmetric sub-pixel having a same structure as the sub-pixel, adjacent to the sub-pixel in a second direction intersecting the first direction, and symmetrical to the sub-pixel with respect to an imaginary symmetric line passing through a center of the source line.

In an embodiment, the sub-pixel and the symmetric sub-pixel may share the source line.

In an embodiment, an entirety of the gate electrode may overlap the sensing signal line.

In an embodiment, each of the gate electrode and the sensing signal line may extend in the first direction.

In an embodiment, each of the gate electrode and the sensing signal line may extend in the first direction and the active pattern may extend in the second direction.

In an embodiment, the display device may further include an insulating layer disposed between the gate electrode and the sensing signal line. The sensing signal line may be electrically connected to the gate electrode through a contact hole formed by removing a portion of the insulating layer.

In an embodiment, the contact hole may be spaced apart from the active pattern in a plan view.

In an embodiment, the source line and the sensing signal line may be disposed on a same layer.

In an embodiment, the source line and the sensing signal line may extend in a same direction.

In an embodiment, the display device may further include an insulating layer disposed between the gate electrode and the sensing signal line. The source line may be electrically connected to the active pattern through a contact hole formed by removing a portion of the insulating layer.

In an embodiment, the sub-pixel may further include a storage capacitor including a first electrode and a second electrode. The first electrode and the gate electrode may be disposed on a same layer. The second electrode and the sensing signal line may be disposed on a same layer.

In an embodiment, a length of the sensing signal line in the first direction may be greater than a length of the gate electrode in the first direction.

In an embodiment, the gate electrode and the sensing signal line may include a same conductive material.

In an embodiment, the active pattern may include a first portion, and a second portion having a planer shape symmetrical to the first portion with respect to the imaginary symmetric line. The transistor may include the second portion of the active pattern.

In an embodiment, the display device may further include a data line disposed between the substrate and the active pattern. The data line may extend in the second direction, and the gate electrode may extend in the first direction.

In an embodiment, each of the sub-pixel and the symmetric sub-pixel may be one of a red sub-pixel, a green sub-pixel, and a blue sub-pixel.

A display device according to embodiments of the disclosure may include a substrate, a sub-pixel including a transistor disposed on the substrate, and a light emitting element disposed on the transistor, a source line extending in a first direction, electrically connected to the transistor, and that transmits an initialization voltage to the transistor, and a symmetric sub-pixel having a same structure as the sub-pixel, adjacent to the sub-pixel in a second direction intersecting the first direction, and symmetrical to the sub-pixel with respect to an imaginary symmetric line passing through a center of the source line.

In an embodiment, the sub-pixel and the symmetric sub-pixel may share the source line.

In an embodiment, the transistor may include an active pattern disposed on the substrate, and a gate electrode defining a channel area in an area overlapping the active pattern.

In an embodiment, the sub-pixel may further include a storage capacitor including a first electrode and a second electrode. The first electrode and the gate electrode may be disposed on a same layer, and the second electrode and the source line may be disposed on a same layer.

A display device according to an embodiment of the disclosure may include a sub-pixel including a transistor and a light emitting element disposed on the transistor, a source line extending in a first direction and connected to the transistor to transmit an initialization voltage to the transistor, and a symmetric sub-pixel adjacent to the sub-pixel in a second direction and symmetrical to the sub-pixel with respect to an imaginary symmetric line passing through a center of the source line. Accordingly, the capacity of a storage capacitor may increase. Since the sub-pixel and the symmetric sub-pixel may share the source line, a space where lines may be disposed may be additionally allocated. Accordingly, the display quality of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic cross-sectional view illustrating a display device according to an embodiment.

FIG. 2 is a schematic circuit diagram illustrating a sub-pixel of the display device of FIG. 1.

FIG. 3 is a schematic cross-sectional view illustrating an example of the display device of FIG. 1.

FIG. 4 is a schematic layout view illustrating a pixel included in the display device of FIG. 1.

FIGS. 5, 6, 7, and 8 are schematic layout views illustrating the components shown in the layout diagram of FIG. 4 for each layer.

FIG. 9 is a schematic cross-sectional view taken along line I-I′ of FIG. 4.

FIG. 10 is a schematic cross-sectional view taken along line II-II′ of FIG. 4.

FIG. 11 is a schematic cross-sectional view taken along line of FIG. 4.

FIG. 12 is a schematic cross-sectional view taken along line IV-IV′ of FIG. 4.

FIG. 13 is a schematic cross-sectional view illustrating a display device according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

It will be understood that the terms “connected to” or “coupled to” may include a physical or electrical connection or coupling.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

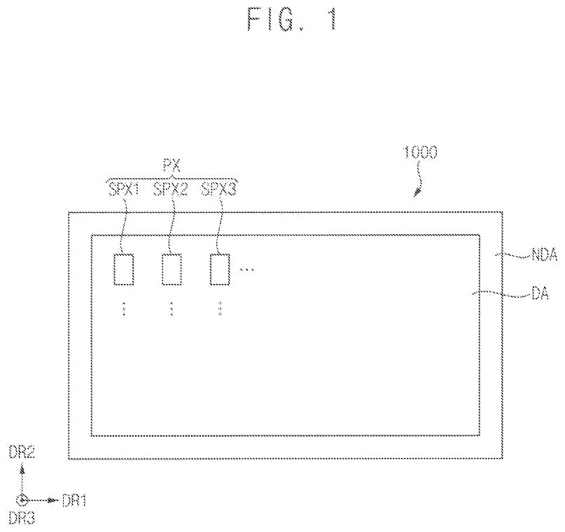

FIG. 1 is a schematic cross-sectional view illustrating a display device according to an embodiment.

Referring to FIG. 1, a display device 1000 according to an embodiment may be divided into a display area DA and a non-display area NDA. The display area DA may be an area capable of displaying an image by generating light or adjusting transmittance of light provided from an external light source. The non-display area NDA may be an area that does not display an image. The non-display area NDA may be located around the display area DA. For example, the non-display area NDA may surround the display area DA.

In a plan view, the display device 1000 may have a rectangular shape. However, the disclosure is not limited thereto, and the display device 1000 may have various shapes in a plan view.

The display device 1000 may include pixels PX disposed in the display area DA. As the pixels PX emit light, the display area DA may display an image.

Each of the pixels PX may include a first sub-pixel SPX1, a second sub-pixel SPX2, and a third sub-pixel SPX3. In an embodiment, the first sub-pixel SPX1 may be a red sub-pixel that emits red light, the second sub-pixel SPX2 may be a green sub-pixel that emits green light, and the third sub-pixel SPX3 may be a blue sub-pixel that emits blue light. However, a color of the light emitted by each of the sub-pixels SPX1, SPX2, and SPX3 is not limited thereto. Although FIG. 1 shows that there are the three sub-pixels SPX1, SPX2, and SPX3, the disclosure is not limited thereto. For example, each of the pixels PX may further include a fourth sub-pixel that emits white light.

The pixels PX may be repeatedly arranged in the first direction DR1 and the second direction DR2 crossing the first direction DR1. Accordingly, each of the first sub-pixel SPX1, the second sub-pixel SPX2, and the third sub-pixel SPX3 may be repeatedly arranged in the first direction DR1 and the second direction DR2.

The display device 1000 may include drivers disposed in the non-display area NDA. For example, the drivers may include a gate driver, a data driver, and the like. The drivers may be electrically connected to the pixel PX. The drivers may provide signals and voltages for emitting the light to the pixel PX.

A plane may be defined in the first direction DR1 and the second direction DR2 intersecting the first direction DR1. For example, the first direction DR1 may be perpendicular to the second direction DR2. The third direction DR3 may be perpendicular to the plane.

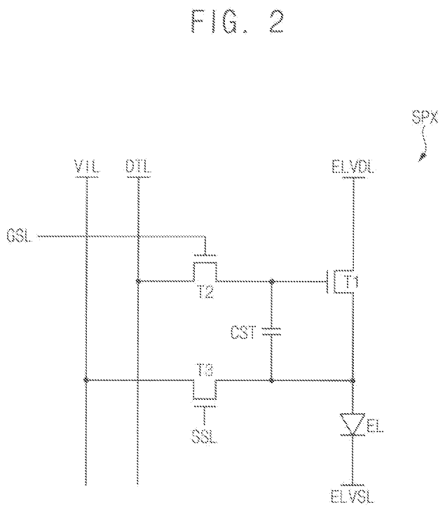

FIG. 2 is a schematic circuit diagram illustrating a sub-pixel of the display device of FIG. 1. For example, the circuit diagram shown in FIG. 2 is a circuit diagram illustrating any one of the first, second, and third sub-pixels SPX1, SPX2, and SPX3 shown in FIG. 1.

Referring to FIG. 2, each of the first, second, and third sub-pixels SPX1, SPX2, and SPX3 of the display device 1000 according to an embodiment may include first, second, and third transistors T1, T2, and T3, a storage capacitor CST, and a light emitting element EL.

The first transistor T1 may adjust a current flowing from a driving voltage line ELVDL to which a driving voltage may be supplied to the light emitting element EL according to a voltage difference between the gate electrode and the source electrode. For example, the first transistor T1 may be a driving transistor for driving the light emitting element EL. The gate electrode of the first transistor T1 may be connected to the source electrode of the second transistor T2, the source electrode of the first transistor T1 may be connected to the first electrode of the light emitting element EL, and the drain electrode of the first transistor T1 may be connected to the driving voltage line ELVDL to which the driving voltage may be applied.

The second transistor T2 may be turned on by a gate signal of the gate signal line GSL to connect a data line DTL to the gate electrode of the first transistor T1. The gate electrode of the second transistor T2 may be connected to the gate signal line GSL, the source electrode of the second transistor T2 may be connected to the gate electrode of the first transistor T1, and the drain electrode of the second transistor T2 may be connected to the data line DTL.

The third transistor T3 may be turned on by a sensing signal of the sensing signal line SSL to connect an initialization voltage line VIL to an end of the light emitting element EL. The gate electrode of the third transistor T3 may be connected to the sensing signal line SSL, the drain electrode of the third transistor T3 may be connected to the initialization voltage line VIL, and the source electrode of the third transistor T3 may be connected to an end of the light emitting element EL or the source electrode of the first transistor T1.

However, the source electrode and the drain electrode of each of the first, second, and third transistors T1, T2, and T3 are not limited thereto, and an opposite may be a case. Each of the first, second, and third transistors T1, T2, and T3 may be formed of a thin film transistor.

The storage capacitor CST may be formed between the gate electrode and the source electrode of the first transistor T1. The storage capacitor CST may store a difference voltage between the gate voltage and the source voltage of the first transistor T1.

The light emitting element EL may emit light according to the current supplied through the first transistor T1. The light emitting element EL may be an organic light emitting diode including a first electrode (e.g., an anode electrode), an organic light emitting layer, and a second electrode (e.g., a cathode electrode). However, the disclosure is not limited thereto. The first electrode of the light emitting element EL may be connected to the source electrode of the first transistor T1, and the second electrode of the light emitting element EL may be connected to a common voltage line ELVSL to which a common voltage lower than the driving voltage may be applied.

However, although the case in which each sub-pixel SPX includes three transistors and a storage capacitor has been described in FIG. 2, the disclosure is not limited thereto.

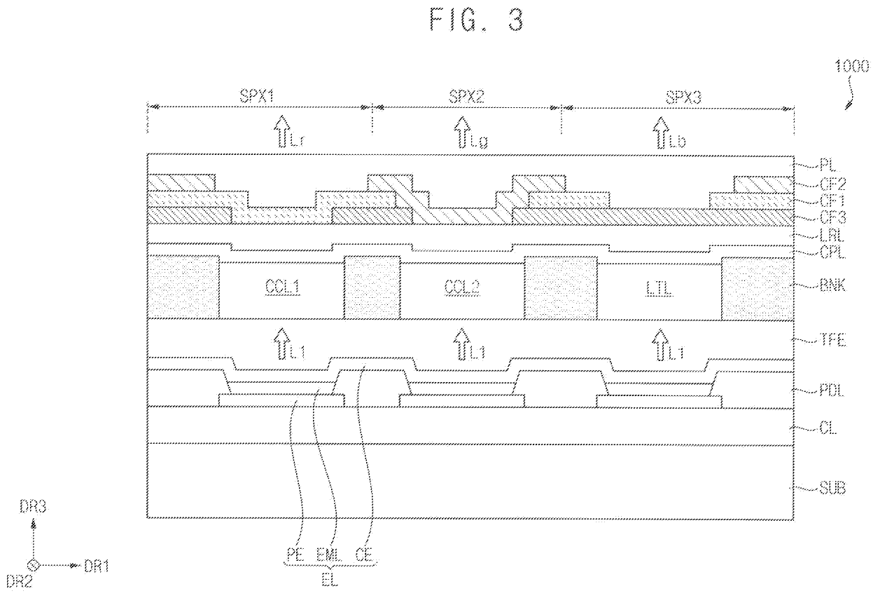

FIG. 3 is a schematic cross-sectional view illustrating an example of the display device of FIG. 1. For example, FIG. 3 shows an example of a cross-section of the display area DA of FIG. 1.

Referring to FIG. 3, the display device 1000 according to an embodiment may include a substrate SUB, a circuit layer CL, a pixel defining layer PDL, a light emitting element EL, an encapsulation structure TFE, a bank layer BNK, first and second color conversion layers CCL1 and CCL2, a light transmission layer LTL, a capping layer CPL, a low refractive layer LRL, first, second, and third color filter layers CF1, CF2, and CF3, and a protective layer PL. Here, the light emitting element EL may include a pixel electrode PE, a light emitting layer EML, and a common electrode CE.

The substrate SUB may include a transparent material or an opaque material. The substrate SUB may be formed of a transparent resin substrate. An example of the transparent resin substrate may include a polyimide substrate, and the like. The polyimide substrate may include a first organic layer, a first barrier layer, a second organic layer, and the like. In other embodiments, the substrate SUB may include a quartz substrate, a synthetic quartz substrate, a calcium fluoride substrate, a fluorine-doped quartz substrate, a sodalime substrate, a non-alkali glass substrate, and the like. These may be used alone or in combination with each other.

The circuit layer CL may be disposed on the substrate SUB. The circuit layer CL may provide signals and voltages for the light emitting element EL to emit light to the light emitting element EL. For example, the circuit layer CL may include a transistor, a conductive layer, an insulating layer, and the like.

The pixel electrode PE may be disposed on the circuit layer CL. The pixel electrode PE may receive the signals and the voltages from the circuit layer CL. For example, the pixel electrode PE may include a metal, an alloy, a metal nitride, a conductive metal oxide, a transparent conductive material, and the like. These may be used alone or in combination with each other. For example, the pixel electrode PE may be an anode electrode. In other embodiments, the pixel electrode PE may be a cathode electrode.

The pixel defining layer PDL may be disposed on the circuit layer CL and the pixel electrode PE. The pixel defining layer PDL may have an opening exposing a portion of the pixel electrode PE. Since the pixel defining layer PDL has the opening, the pixel defining layer PDL may define each of the sub-pixels SPX1, SPX2, and SPX3 that emits light. The pixel defining layer PDL may include an organic material or an inorganic material. Examples of the organic material that can be used as the pixel defining layer PDL may be photoresists, polyacrylic resins, polyimide-based resins, polyamide-based resins, siloxane-based resins, acrylic-based resins, epoxy-based resins, and the like. These may be used alone or in combination with each other.

The light emitting layer EML may be disposed on the pixel electrode PE. Specifically, the light emitting layer EML may be disposed in the opening of the pixel defining layer PDL. The light emitting layer EML may include materials for emitting light. For example, the light emitting layer EML may include an organic light emitting material or an inorganic light emitting material.

The common electrode CE may be disposed on the pixel defining layer PDL and the light emitting layer EML. For example, the common electrode CE may include a metal, an alloy, a metal nitride, a conductive metal oxide, a transparent conductive material, and the like. These may be used alone or in combination with each other. For example, the common electrode CE may be a cathode electrode. In other embodiments, the common electrode CE may be an anode electrode.

Accordingly, the light emitting element EL including the pixel electrode PE, the light emitting layer EML, and the common electrode CE may be disposed on the substrate SUB. Each of the first, second, and third sub-pixels SPX1, SPX2, and SPX3 may include the light emitting element EL.

The encapsulation structure TFE may be disposed on the common electrode CE. The encapsulation structure TFE may prevent impurities, moisture, and the like from penetrating into the light emitting element EL from an outside. The encapsulation structure TFE may include at least one inorganic encapsulation layer and at least one organic encapsulation layer. For example, the inorganic encapsulation layer may include silicon oxide, silicon nitride, and/or silicon oxynitride. The organic encapsulation layer may include a cured polymer such as polyacrylate, and the like.

The bank layer BNK may be disposed on the encapsulation structure TFE. The bank layer BNK may surround the first color conversion layer CCL1, the second color conversion layer CCL2, and the light transmission layer LTL. A space for accommodating an ink composition may be formed in the bank layer BNK during the formation of the first color conversion layer CCL1, the second color conversion layer CCL2, and the light transmission layer LTL. Accordingly, in a plan view, the bank layer BNK may have a grid shape or a matrix shape. For example, the bank layer BNK may include an organic material.

The first color conversion layer CCL1, the second color conversion layer CCL2, and the light transmission layer LTL may be disposed on the encapsulation structure TFE. The first and second color conversion layers CCL1 and CCL2 may convert light emitted from the light emitting element EL into light having a specific wavelength.

The first color conversion layer CCL1 may overlap an area where the first sub-pixel SPX1 may be disposed, the second color conversion layer CCL2 may overlap an area where the second sub-pixel SPX2 may be disposed, and the light transmission layer LTL may overlap an area where the third sub-pixel SPX3 may be disposed.

The first color conversion layer CCL1 may convert light L1 (e.g., blue light) emitted from the light emitting element EL into light Lr of a first color. The second color conversion layer CCL2 may convert the light L1 emitted from the light emitting element EL into light Lg of a second color. The light transmission layer LTL may transmit the light L1 emitted from the light emitting element EL. In an embodiment, the first color may be red, and the second color may be green. The light transmission layer LTL may transmit blue light Lb. However, the disclosure is not limited thereto.

The first color conversion layer CCL1 may include a first color conversion particle that may be excited by the light L1 generated from the light emitting element EL and emit the light of the first color (e.g., the red light Lr). The first color conversion layer CCL1 may further include a first photosensitive polymer in which first scattering particles may be dispersed.

The second color conversion layer CCL2 may include a second color conversion particle that may be excited by the light L1 generated from the light emitting element EL and emit the light of the second color (e.g., the green light Lg). The second color conversion layer CCL2 may further include a second photosensitive polymer in which second scattering particles may be dispersed. Each of the first color conversion particle and the second color conversion particle may denote a quantum dot.

The light transmission layer LTL may transmit the light L1 generated from the light emitting element EL and emit the light L1 in a direction of the protective layer PL. The light transmission layer LTL may include a third photosensitive polymer in which third scattering particles may be dispersed.

For example, each of the first, second, and third photosensitive polymers may include an organic material having light transmittance, such as a silicone resin, an epoxy resin, and the like, or a combination thereof. The first, second, and third photosensitive polymers may include the same material. The first, second, and third scattering particles may scatter and emit the light L1 generated from the light emitting element EL, and the first, second, and third scattering particles may include the same material.

The capping layer CPL may be disposed on the bank layer BNK, the first color conversion layer CCL1, the second color conversion layer CCL2, and the light transmission layer LTL. The capping layer CPL may serve to prevent moisture permeation to prevent deterioration of the first color conversion layer CCL1, the second color conversion layer CCL2, and the light transmission layer LTL. For example, the capping layer CPL may include a silicon compound.

The low refractive index layer LRL may be disposed on the capping layer CPL. The low refractive index layer LRL may have a relatively low refractive index. For example, a refractive index of the low refractive index layer LRL may be lower than a refractive index of each of the first color conversion layer CCL1, the second color conversion layer CCL2, and the light transmission layer LTL. The low refractive index layer LRL may include an organic material. For example, the low refractive index layer LRL may include an organic polymer material including silicon.

The first, second, and third color filter layers CF1, CF2, and CF3 may be disposed on the low refractive index layer LRL. Specifically, the first, second, and third color filter layers CF1, CF2, and CF3 may be disposed on the low refractive index layer LRL in an order of the third color filter layer CF3, the first color filter layer CF1, and the second color filter layer CF2. The first, second, and third color filter layers CF1, CF2, and CF3 may selectively transmit light having a specific wavelength.

The first color filter layer CF1 may partially overlap the first color conversion layer CCL1, the second color filter layer CF2 may partially overlap the second color conversion layer CCL2, and the third color filter layer CF3 may partially overlap the light transmission layer LTL.

For example, the first color filter layer CF1 may transmit the red light Lr and block lights having a color different from a color of the red light Lr. The second color filter layer CF2 may transmit the green light Lg and block lights having a color different from a color of the green light Lg. For example, the third color filter layer CF3 may transmit the blue light Lb and block light having a color different from a color of the blue light Lb.

The protective layer PL may be disposed on the first, second, and third color filter layers CF1, CF2, and CF3. The protective layer PL may cover the first, second, and third color filter layers CF1, CF2, and CF3. For example, the protective layer PL may include an inorganic material or an organic material.

However, although the display device 1000 of the disclosure is shown as an organic light emitting display device (OLED), the configuration of the disclosure is not limited thereto. In other embodiments, the display device 1000 may include a liquid crystal display device (LCD), a field emission display device (FED), a plasma display device (PDP), an electrophoretic display device (EPD), a quantum dot display device, or an inorganic light emitting display device.

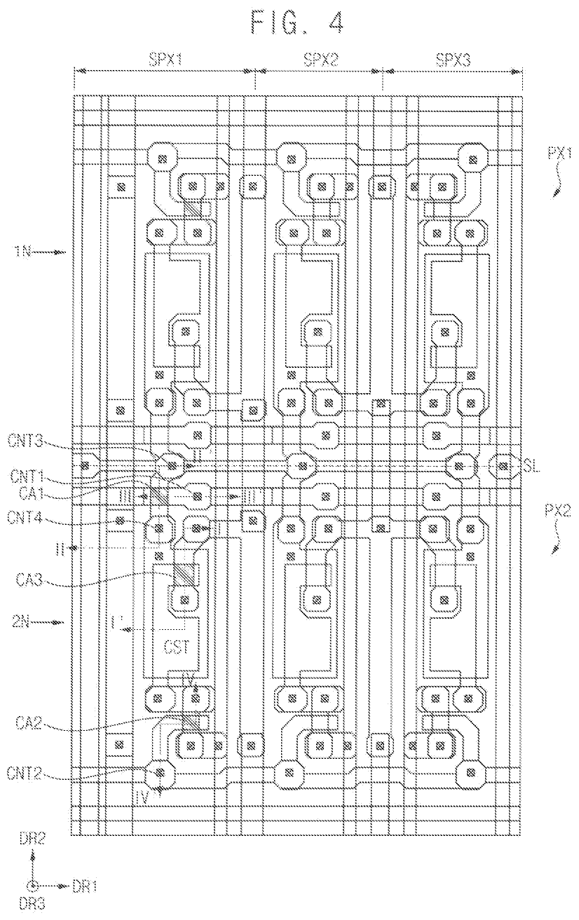

FIG. 4 is a schematic layout view illustrating a pixel included in the display device of FIG. 1. For example, FIG. 4 may be an example of a plan view illustrating the circuit layer CL of FIG. 3. The light emitting element EL of FIG. 3 may be disposed on the layout view shown in FIG. 4.

Referring to FIG. 4, as described with reference to FIG. 1, each of the pixels PX may include the first sub-pixel SPX1, the second sub-pixel SPX2, and the third sub-pixel SPX3. The first, second, and third sub-pixels SPX1, SPX2, and SPX3 may include the same component.

For example, the pixels PX may include a first pixel PX1 and a second pixel PX2. The second pixel PX2 may be adjacent to the first pixel PX1 in a direction opposite to the second direction DR2 crossing the first direction DR1. For example, the first pixel PX1 may be repeatedly disposed in a first row 1N in the first direction DR1, and the second pixel PX2 may be repeatedly disposed in a second row 2N adjacent to the first row 1N in the first direction DR1. Such pixel arrangement may be repeated up to a row.

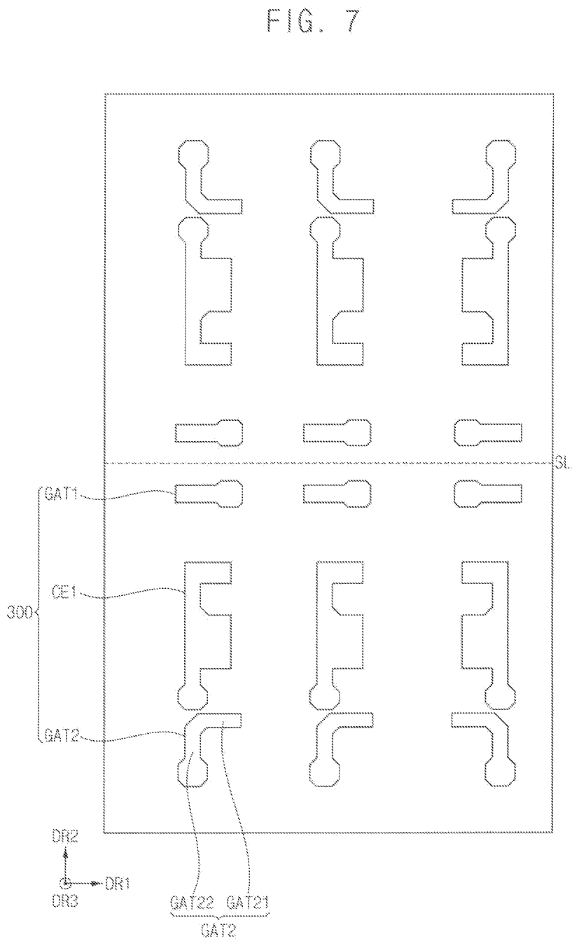

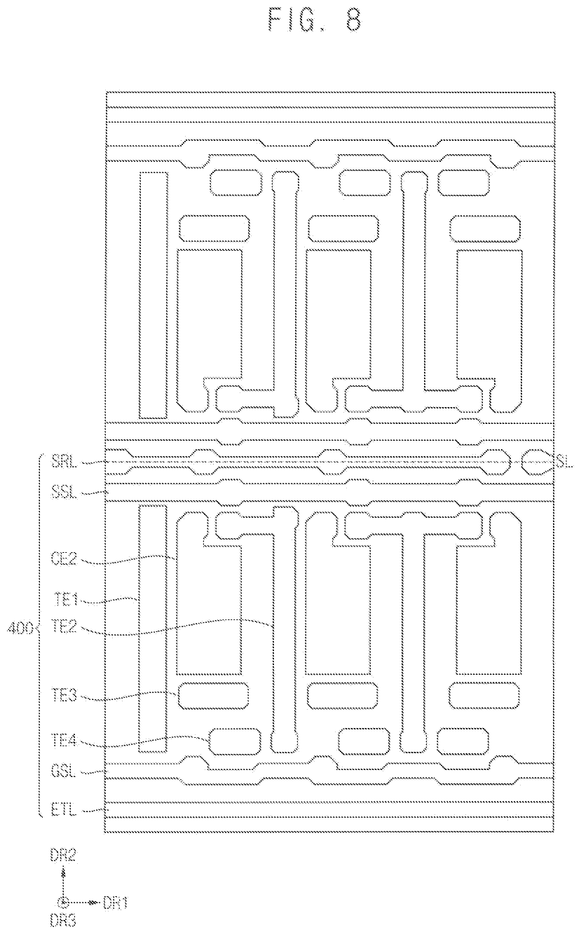

In an embodiment, the first pixel PX1 and the second pixel PX2 may be symmetric with each other with respect to an imaginary symmetric line SL passing through a center of a source line (e.g., a source line SRL shown in FIG. 8). For example, the first pixel PX1 and the second pixel PX2 may have the same structure. In other words, each of the first pixel PX1 and the second pixel PX2 may include the first sub-pixel SPX1, the second sub-pixel SPX2, and the third sub-pixel SPX3 including the same component.

In the specification, each of the sub-pixels SPX1, SPX2, and SPX3 of the first pixel PX1 may be defined as a sub-pixel, and each of the sub-pixels SPX1, SPX2, and SPX3 of the second pixel PX2 may be defined as a symmetric sub-pixel.

Hereinafter, since the first, second, and third sub-pixels SPX1, SPX2, and SPX3 have the same component, a sub-pixel (e.g., the first sub-pixel SPX1) will be described in detail.

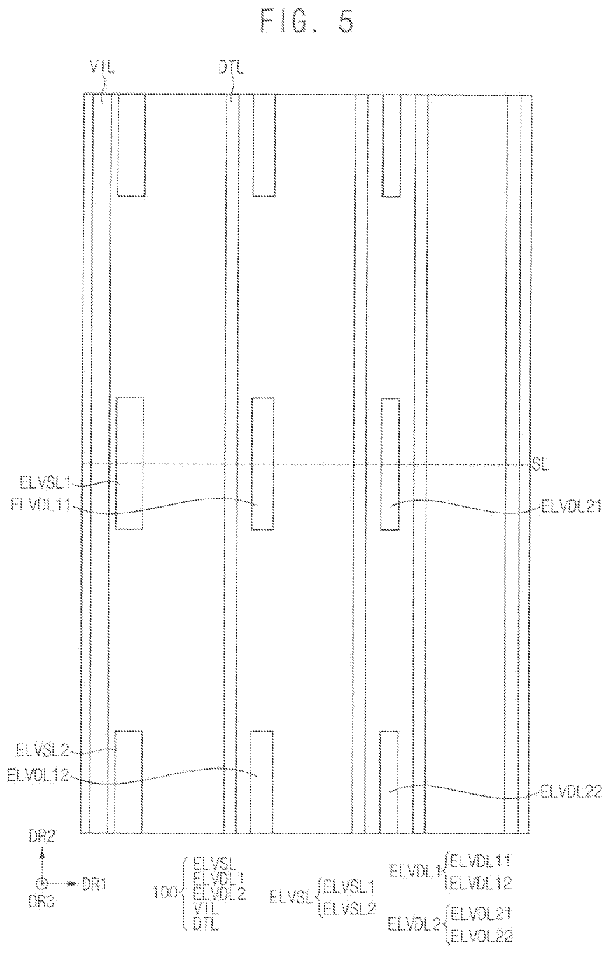

FIGS. 5, 6, 7, and 8 are schematic layout views illustrating the components shown in the layout diagram of FIG. 4 for each layer.

Referring to FIGS. 3, 4, and 5, the display device 1000 according to an embodiment may further include a first conductive layer 100. The first conductive layer 100 may be disposed on the substrate SUB.

The first conductive layer 100 may include first and second driving voltage lines ELVDL1 and ELVDL2, a common voltage line ELVSL, an initialization voltage line VIL, and a data line DTL.

The first driving voltage line ELVDL1 and the second driving voltage line ELVDL2 may be spaced apart from each other. For example, the second driving voltage line ELVDL2 may be spaced apart from each other in the first direction DR1 from the first driving voltage line ELVDL1. In an embodiment, in a plan view, the first driving voltage line ELVDL1 may be located between the first sub-pixel SPX1 and the second sub-pixel SPX2, and the second driving voltage line ELVDL2 may be located between the second sub-pixel SPX2 and the third sub-pixel SPX3.

Each of the first and second driving voltage lines ELVDL1 and ELVDL2 may include a first portion ELVDL11 and ELVDL21 and a second portion ELVDL12 and ELVDL22. The first portion ELVDL11 and ELVDL21 and the second portion ELVDL12 and ELVDL22 may be spaced apart from each other. In detail, the first portion ELVDL11 and ELVDL21 and the second portion ELVDL12 and ELVDL22 may be spaced apart from each other in the second direction DR2 crossing the first direction DR1. In an embodiment, the first pixel PX1 and the second pixel PX2 may share the first portion ELVDL11 of the first driving voltage line ELVDL1 and the first portion ELVDL21 of the second driving voltage line ELVDL2.

The common voltage line ELVSL may include a first portion ELVSL1 and a second portion ELVSL2. The first portion ELVSL1 and the second portion ELVSL2 may be spaced apart from each other. In detail, the first portion ELVSL1 and the second portion ELVSL2 may be spaced apart from each other in the second direction DR2. In an embodiment, the first pixel PX1 and the second pixel PX2 may share the first portion ELVSL1 of the common voltage line ELVSL.

The first and second driving voltage lines ELVD1 and ELVDL2 may transmit the driving voltage to the first transistor (e.g., the first transistor T1 shown in FIG. 2). The common voltage line ELVSL may transmit the common voltage to the light emitting element (e.g., the light emitting element EL shown in FIG. 2). The initialization voltage line VIL may transmit the initialization voltage to the third transistor (e.g., the third transistor T3 shown in FIG. 2). For example, the driving voltage may be greater than the common voltage, and the initialization voltage may be a preset voltage.

Each of the first and second driving voltage lines ELVDL1 and ELVDL2, the common voltage line ELVSL, the initialization voltage line VIL, and the data line DTL may extend in the second direction DR2. For example, the first and second driving voltage lines ELVDL1 and ELVDL2, the common voltage line ELVSL, the initialization voltage line VIL, and the data line DTL may extend in the same direction.

The first conductive layer 100 may include a metal, an alloy, a conductive metal oxide, a transparent conductive material, and the like. Examples of the metal that may be used for the first conductive layer 100 may be silver (Ag), molybdenum (Mo), aluminum (Al), tungsten (W), copper (Cu), nickel (Ni), chromium. (Cr), titanium (T1), tantalum (Ta), platinum (Pt), scandium (Sc), indium (In), and the like. Examples of the conductive metal oxide that may be used for the first conductive layer 100 may be indium tin oxide (ITO), indium zinc oxide (IZO), indium tin zinc oxide (ITZO), and the like. These may be used alone or in combination with each other. However, materials that can be used for the first conductive layer 100 are not limited thereto.

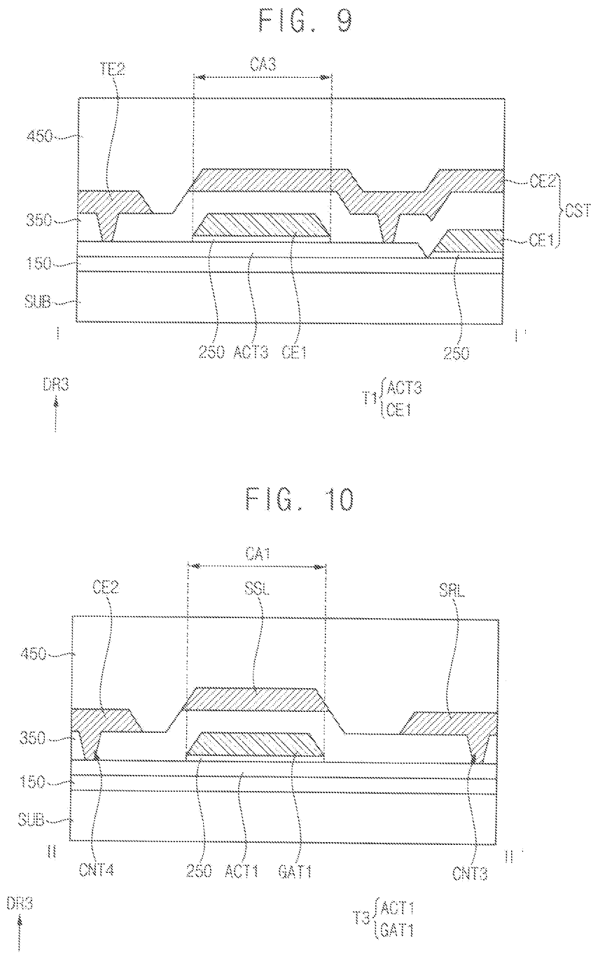

Referring to FIGS. 3, 4, and 6, the display device 1000 according to an embodiment of the disclosure may further include an active layer 200. The active layer 200 may be disposed on the first conductive layer 100. Specifically, a buffer layer (e.g., a buffer layer 150 shown in FIG. 9) covering the first conductive layer 100 may be disposed on the first conductive layer 100 and the active layer 200 may be disposed on the buffer layer.

The active layer 200 may include a first active pattern ACT1, a second active pattern ACT2, and a third active pattern ACT3. In an embodiment, the first pixel PX1 and the second pixel PX2 may share the first active pattern ACT1. For example, the transistor of the first pixel PX1 (e.g., the third transistor T3 shown in FIG. 2) may include a first portion of the first active pattern ACT1 and the transistor of the second pixel PX2 (e.g., the third transistor T3 shown in FIG. 2) may include a second portion of the first active pattern ACT1. The first portion and the second portion may have planar shape symmetrical to each other with respect to the imaginary symmetric line SL extending in the first direction DR1.

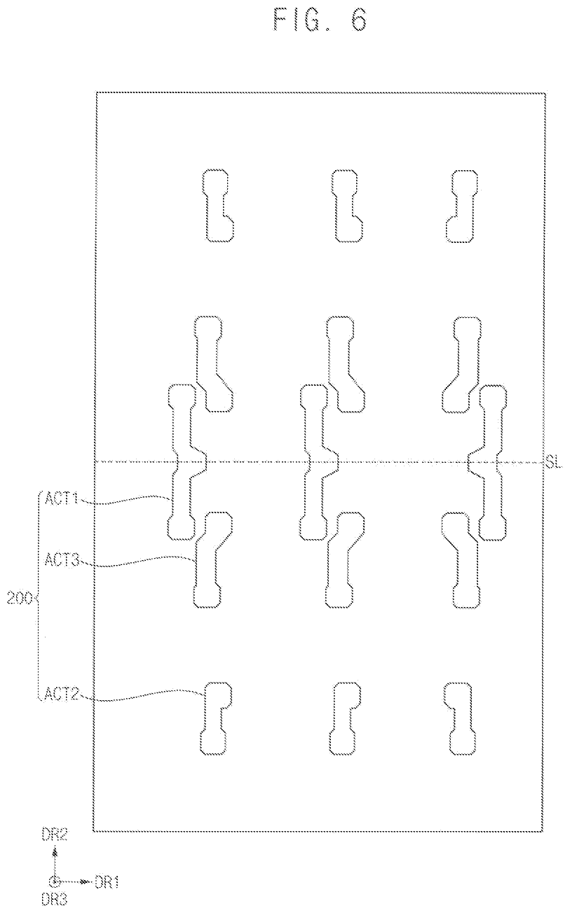

The first to third active patterns ACT1, ACT2, and ACT3 may be disposed on the same layer (e.g., the buffer layer 150 shown in FIG. 9). The first, second, and third active patterns ACT1, ACT2, and ACT3 may be spaced apart from each other in the second direction DR2 crossing the first direction DR1. Each of the first, second, and third active patterns ACT1, ACT2, and ACT3 may extend in the second direction DR2. However, although the number of active patterns ACT1, ACT2, and ACT3 is shown as three in FIGS. 4 and 6, the disclosure is not limited thereto, and the active layer 200 may include various numbers of active patterns.

The active layer 200 may include a metal oxide semiconductor (e.g., indium gallium zinc oxide (IGZO)), an inorganic semiconductor (e.g., amorphous silicon, polysilicon), and/or an organic semiconductor.

Referring to FIGS. 3, 4, and 7, the display device 1000 according to an embodiment may further include a second conductive layer 300. The second conductive layer 300 may be disposed on the active layer 200. Specifically, a first insulating layer (e.g., a first insulating layer 250 shown in FIG. 9) covering the active layer 200 may be disposed on the active layer 200, and the second conductive layer 300 may be disposed on the first insulating layer.

The second conductive layer 300 may include a first gate electrode GAT1, a second gate electrode GAT2, and a first electrode CE1. The first gate electrode GAT1, the second gate electrode GAT2, and the first electrode CE1 may be disposed on the same layer (e.g., the first insulating layer 250 shown in FIG. 9).

The first gate electrode GAT1 may extend in the first direction DR1. The second gate electrode GAT2 may include a first portion GAT21 and a second portion GAT22. The first portion GAT21 may extend in the first direction DR1. The second portion GAT22 may extend in a second direction DR2 crossing the first direction DR1. For example, the second gate electrode GAT2 may have a curved shape in a plan view.

For example, the second conductive layer 300 may include a metal, an alloy, a conductive metal oxide, a transparent conductive material, and the like. These may be used alone or in combination with each other.

Referring to FIGS. 3, 4, and 8, the display device 1000 according to an embodiment may further include a third conductive layer 400. The third conductive layer 400 may be disposed on the second conductive layer 300. Specifically, a second insulating layer (e.g., a second insulating layer 350 shown in FIG. 9) covering the second conductive layer 300 may be disposed on the second conductive layer 300, and the third conductive layer 400 may be disposed on the second insulating layer.

The third conductive layer 400 may include a source line SRL, a sensing signal line SSL, a gate signal line GSL, a second electrode CE2, first, second, third, and fourth transmission electrodes TE1, TE2, TE3, and TE4, and an extension line ETL. The source line SRL, the sensing signal line SSL, the gate signal line GSL, the second electrode CE2, the first, second, third, and fourth transmission electrodes TE1, TE2, TE3, and TE4, and the extension line ETL may be disposed on the same layer (e.g., the second insulating layer 350 shown in FIG. 9).

In an embodiment, the first pixel PX1 and the second pixel PX2 may share the source line SRL. The sub-pixel (e.g., the first sub-pixel SPX1) of the first pixel PX1 and the symmetric sub-pixel (e.g., the first sub-pixel SPX1) of the second pixel PX2 may share the source line SRL. For example, a first portion of the source line SRL may be located in the first pixel PX1, and a second portion of the source line SRL may be located in the second pixel PX2. The first portion and the second portion may have a planar shape symmetrical to each other with respect to the imaginary symmetric line SL extending in the first direction DR1.

Each of the gate signal line GSL, the sensing signal line SSL, and the source line SRL may extend in the first direction DR1. For example, the gate signal line GSL, the sensing signal line SSL, and the source line SRL may extend in the same direction.

The first transmission electrode TE1 may extend in the second direction DR2. The second transmission electrode TE2 may include a portion extending in the first direction DR1 and a portion extending in the second direction DR2. The third transmission electrode TE3 and the fourth transmission electrode TE4 may extend in the first direction DR1.

A light emitting element (e.g., the light emitting element EL shown in FIG. 3) may be disposed on the third conductive layer 400. The light emitting element may be electrically connected to the third conductive layer 400 through a contact hole.

Hereinafter, an arrangement relationship between the first conductive layer 100, the active layer 200, the second conductive layer 300, and the third conductive layer 400 of the display device 1000 according to an embodiment of the disclosure will be described with reference to FIGS. 4, 5, 6, 7, and 8.

Referring to FIGS. 4, 5, 6, 7, and 8, a common voltage line ELVSL and two driving voltage lines ELVDL1 and ELVDL2 may be connected to a pixel PX. However, the configuration of the disclosure is not limited thereto, and various numbers of common voltage lines and various numbers of driving voltage lines may be connected to a pixel PX.

The second electrode CE2 may constitute the storage capacitor CST together with the first electrode CE1. To this end, the second electrode CE2 may overlap the first electrode CE1. Since the first, second, and third sub-pixels SPX1, SPX2, and SPX3 may include the same component, each of the first, second, and third sub-pixels SPX1, SPX2, and SPX3 may include a storage capacitor CST. Accordingly, the storage capacitor CST of each of the first to third sub-pixels SPX1, SPX2, and SPX3 may be disposed in the first direction DR1.

The first gate electrode GAT1 may overlap the first active pattern ACT1. Specifically, the first gate electrode GAT1 may partially overlap the first active pattern ACT1. As the first gate electrode GAT1 may be disposed to partially overlap the first active pattern ACT1, the first gate electrode GAT1 may define a first channel area CA1 in an area overlapping the first active pattern ACT1.

The second gate electrode GAT2 may overlap the second active pattern ACT2. In detail, the second gate electrode GAT2 may partially overlap the second active pattern ACT2. As the second gate electrode GAT2 may be disposed to partially overlap the second active pattern ACT2, the second gate electrode GAT2 may define a second channel area CA2 in an area overlapping the second active pattern ACT2.

The first electrode CE1 may overlap the third active pattern ACT3. In detail, the first electrode CE1 may partially overlap the third active pattern ACT3. As the first electrode CE1 may be disposed to partially overlap the third active pattern ACT3, the first electrode CE1 may define a third channel area CA3 in an area overlapping the third active pattern ACT3.

The sensing signal line SSL may be disposed on the first gate electrode GAT1. The sensing signal line SSL may overlap the first channel area CA1.

The first gate electrode GAT1 and the sensing signal line SSL may extend in the first direction DR1. For example, the first gate electrode GAT1 and the sensing signal line SSL may extend in the same direction. A length of the sensing signal line SSL in the first direction DR1 may be greater than a length of the first gate electrode GAT1 in the first direction DR1.

The sensing signal line SSL may overlap the first gate electrode GAT1. For example, the sensing signal line SSL may not overlap only the first channel area CA1. In an embodiment, an entirety of the first gate electrode GAT1 may overlap the sensing signal line SSL.

In an embodiment, the first gate electrode GAT1 and the sensing signal line SSL may include the same material. For example, the first gate electrode GAT1 and the sensing signal line SSL may include copper. In another embodiment, the first gate electrode GAT1 and the sensing signal line SSL may include different materials. For example, the first gate electrode GAT1 may include copper, and the sensing signal line SSL may include molybdenum. However, the disclosure is not limited thereto, and the first gate electrode GAT1 and the sensing signal line SSL may include various conductive materials.

The sensing signal line SSL may be electrically connected to the gate driver. Accordingly, the sensing signal line SSL may receive a signal (e.g., the sensing signal) from the gate driver.

The sensing signal line SSL may transmit the sensing signal to the first gate electrode GAT1. For example, the sensing signal line SSL may receive the sensing signal from the gate driver and transmit the sensing signal to the first gate electrode GAT1. The sensing signal may activate the first channel area CA1 of the first active pattern ACT1.

The sensing signal line SSL may be connected to the first gate electrode GAT1 through the first contact hole CNT1. Accordingly, the sensing signal line SSL may transmit the sensing signal to the first gate electrode GAT1. For example, the sensing signal line SSL may transmit the sensing signal to the first channel area CA1. The first contact hole CNT1 may be spaced apart from the first active pattern ACT1 in a plan view. For example, the first contact hole CNT1 may not overlap the first active pattern ACT1.

The gate signal line GSL may be disposed on the second gate electrode GAT2. The gate signal line GSL may be spaced apart from the second channel area CA2 in a plan view. For example, the gate signal line GSL may not overlap the second channel area CA2. In other words, the first portion GAT21 of the second gate electrode GAT2 may not overlap the gate signal line GSL, and the second portion GAT22 of the second gate electrode GAT2 may overlap the gate signal line GSL. The first portion GAT21 of the second gate electrode GAT2 may overlap the second channel area CA2.

In an embodiment, the second gate electrode GAT2 and the gate signal line GSL may include the same material. For example, the second gate electrode GAT2 and the gate signal line GSL may include copper. In another embodiment, the second gate electrode GAT2 and the gate signal line GSL may include different materials. For example, the second gate electrode GAT2 may include copper, and the gate signal line GSL may include molybdenum. However, the disclosure is not limited thereto, and the second gate electrode GAT2 and the gate signal line GSL may include various conductive materials.

The gate signal line GSL may be electrically connected to the gate driver. Accordingly, the gate signal line GSL may receive a signal (e.g., the gate signal) from the gate driver.

The gate signal line GSL may transmit the gate signal to the second gate electrode GAT2. For example, the gate signal line GSL may receive the gate signal from the gate driver and transmit the gate signal to the second gate electrode GAT2. The gate signal may activate the second channel area CA2 of the second active pattern ACT2.

The gate signal line GSL may be connected to the second gate electrode GAT2 through the second contact hole CNT2. Specifically, the gate signal line GSL may be connected to the second portion GAT22 of the second gate electrode GAT2 through the second contact hole CNT2. Accordingly, the gate signal line GSL may transmit the gate signal to the second gate electrode GAT2. For example, the gate signal line GSL may transmit the gate signal to the second channel area CA2. The second contact holes CNT2 may be spaced apart from the second active pattern ACT2 in a plan view. For example, the second contact hole CNT2 may not overlap the second active pattern ACT2.

The source line SRL may be connected to the first active pattern ACT1 through a third contact hole CNT3. A portion of the source line SRL connected to the first active pattern ACT1 may serve as a source electrode. The third contact hole CNT3 may overlap the first active pattern ACT1. The source line SRL may be connected to the initialization voltage line VIL through a contact hole. Accordingly, the initialization voltage line VIL may transmit the initialization voltage to the source line SRL, and the source line SRL may transmit the initialization voltage to the first active pattern ACT1.

The second electrode CE2 may be disposed on the first electrode CE1. The second electrode CE2 may partially overlap the first electrode CE1. A first portion of the second electrode CE2 may be connected to the first active pattern ACT1 through a fourth contact hole CNT4. The first portion of the second electrode CE2 connected to the first active pattern ACT1 may serve as a drain electrode. A second portion of the second electrode CE2 may be connected to the third active pattern ACT3 through a contact hole. The second portion of the second electrode CE2 connected to the third active pattern ACT3 may serve as a drain electrode. Accordingly, the second electrode CE2 may be electrically connected to the light emitting element (e.g., the light emitting element EL shown in FIGS. 2 and 3).

The first transmission electrode TE1 may be disposed on the common voltage line ELVSL. The first transmission electrode TE1 may electrically connect the first portion ELVSL1 and the second portion ELVSL2 of the common voltage line ELVSL through contact holes.

The second transmission electrode TE2 may be disposed on the first driving voltage line ELVDL1. The second transmission electrode TE2 may electrically connect the first portion ELVDL11 and the second portion ELVDL12 of the first driving voltage line ELVDL1 through contact holes. A portion of the second transmission electrode TE2 may be branched in a direction opposite to the first direction DR1 to overlap the third active pattern ACT3. The portion of the second transmission electrode TE2 may be connected to the third active pattern ACT3 through a contact hole. Accordingly, the second transmission electrode TE2 may be electrically connected to the second electrode CE2 through the third active pattern ACT3.

The third transmission electrode TE3 may overlap the second active pattern ACT2 and the first electrode CE1, respectively. The third transmission electrode TE3 may electrically connect the second active pattern ACT2 and the first electrode CE1 through contact holes.

The fourth transmission electrode TE4 may overlap the second active pattern ACT2 and the data line DTL, respectively. The fourth transmission electrode TE4 may electrically connect the second active pattern ACT and the data line DTL through contact holes.

The extension line ETL may partially overlap the first conductive layer 100. For example, the extension line ETL may transmit an auxiliary voltage to a transistor (e.g., the first transistor T1 shown in FIG. 2). The auxiliary voltage may be used as the driving voltage.

Hereinafter, a cross-sectional structure of the display device 1000 according to an embodiment of the disclosure will be described.

FIG. 9 is a schematic cross-sectional view taken along line I-I′ of FIG. 4.

Referring to FIGS. 4 and 9, the buffer layer 150 may be disposed on the substrate SUB. The buffer layer 150 may prevent diffusion of impurities from the substrate SUB to the active layer 200. The buffer layer 150 may control a transfer rate of heat generated in the process of forming the active layer 200. Accordingly, the active layer 200 may be uniformly formed. For example, the buffer layer 150 may include an inorganic insulating material.

The third active pattern ACT3 of the active layer 200 may be disposed on the buffer layer 150. The first insulating layer 250 may be disposed on the buffer layer 150 and the active layer 200. The first insulating layer 250 may be patterned to overlap a portion of the active layer 200. The first insulating layer 250 may be patterned to overlap a portion of the buffer layer 150. For example, the first insulating layer 250 may include an inorganic insulating material. Examples of the inorganic insulating material may include silicon oxide, silicon nitride, silicon oxynitride, titanium oxide, tantalum oxide, and the like. These may be used alone or in combination with each other.

The first electrode CE1 of the second conductive layer 300 may be disposed on the first insulating layer 250. The first electrode CE1 may define the third channel area CA3 in an area overlapping the third active pattern ACT3. A portion of the first electrode CE1 overlapping the third active pattern ACT3 and the third active pattern ACT3 may constitute a first transistor (e.g., the first transistor T1 shown in FIG. 2).

The second insulating layer 350 may be disposed on the active layer 200 and the second conductive layer 300. The second insulating layer 350 may cover the second conductive layer 300. For example, the second insulating layer 350 may include an inorganic insulating material. Examples of the inorganic insulating material may include silicon oxide, silicon nitride, silicon oxynitride, titanium oxide, tantalum oxide, and the like. These may be used alone or in combination with each other.

The second transmission electrode TE2 of the third conductive layer 400 may be disposed on the second insulating layer 350. The second transmission electrode TE2 may be connected to the third active pattern ACT3 through a contact hole formed by removing a portion of the second insulating layer 350. Accordingly, a portion of the second transmission electrode TE2 connected to the third active pattern ACT3 may serve as a source electrode.

The second electrode CE2 of the third conductive layer 400 may be disposed on the second insulating layer 350. The first electrode CE1 and a portion of the second electrode CE2 overlapping the first electrode CE1 may constitute the storage capacitor CST. The second electrode CE2 may be connected to the third active pattern ACT3 through a contact hole formed by removing a portion of the second insulating layer 350. Accordingly, a portion of the second electrode CE2 connected to the third active pattern ACT3 may serve as a drain electrode.

A third insulating layer 450 may be disposed on the second insulating layer 350 and the third conductive layer 400. The third insulating layer 450 may cover the third conductive layer 400. The third insulating layer 450 may include an organic insulating material. Examples of the organic insulating material may include photoresists, polyacrylic-based resin, polyimide-based resin, and the like. These may be used alone or in combination with each other.

FIG. 10 is a schematic cross-sectional view taken along line II-II′ of FIG. 4. However, the same reference numerals are used for the same components as in FIG. 9, and overlapping descriptions of the same components will be omitted.

Referring to FIGS. 4 and 10, the first active pattern ACT1 of the active layer 200 may be disposed on the buffer layer 150. The first gate electrode GAT1 may be disposed on the first active pattern ACT1. The first gate electrode GAT1 may define the first channel area CA1 in an area overlapping the first active pattern ACT1. A portion of the first gate electrode GAT1 overlapping the first active pattern ACT1 and the first active pattern ACT1 may constitute a third transistor (e.g., the third transistor T3 shown in FIG. 2).

The source line SRL of the third conductive layer 400 may be connected to the first active pattern ACT1 through the third contact hole CNT3 formed by removing a portion of the second insulating layer 350. Accordingly, the source line SRL overlapping the first active pattern ACT1 may serve as a source electrode.

The second electrode CE2 of the third conductive layer 400 may be connected to the first active pattern ACT1 through the fourth contact hole CNT4 formed by removing a portion of the second insulating layer 350. Accordingly, the second electrode CE2 overlapping the first active pattern ACT1 may serve as a drain electrode.

The sensing signal line SSL of the third conductive layer 400 may overlap the first active pattern ACT1 and the first gate electrode GAT1. In other words, the sensing signal line SSL may overlap the first gate electrode GAT1 in the first channel area CA1. However, the sensing signal line SSL may not contact the first gate electrode GAT1 in the first channel area CA1.

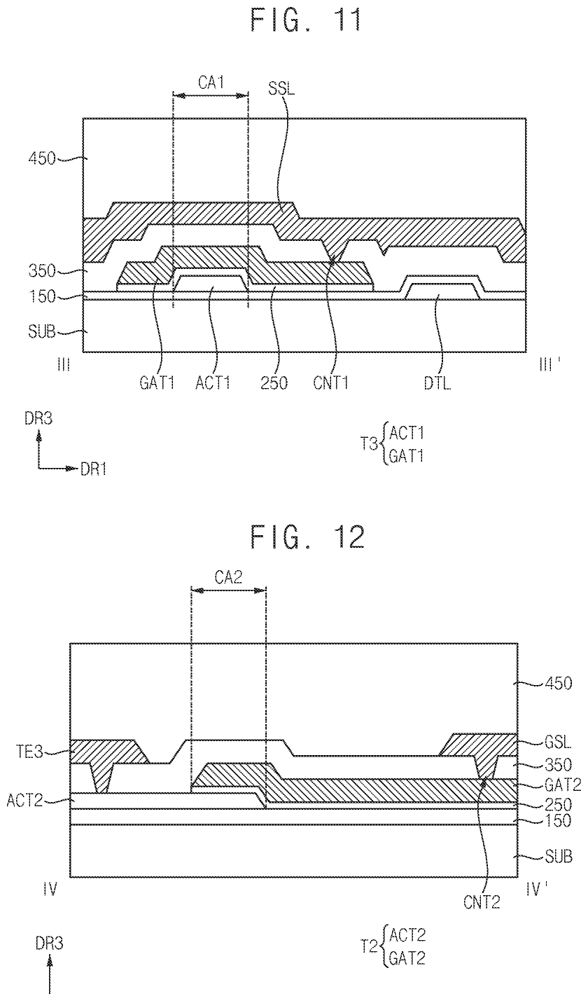

FIG. 11 is a schematic cross-sectional view taken along line of FIG. 4. However, the same reference numerals are used for the same components as in FIGS. 9 and 10, and overlapping descriptions of the same components will be omitted.

Referring to FIGS. 4 and 11, the data line DTL may be disposed on the substrate SUB. The buffer layer 150 may be disposed on the data line DTL. The buffer layer 150 may cover the data line DTL.

The sensing signal line SSL may entirely overlap the first gate electrode GAT1. In detail, an entirety of the first gate electrode GAT1 may overlap the sensing signal line SSL.

The sensing signal line SSL may be connected to the first gate electrode GAT1 through the first contact hole CNT1 formed by removing a portion of the second insulating layer 350. For example, the sensing signal line SSL may be electrically connected to the first gate electrode GAT1 through the first contact hole CNT1. Accordingly, the sensing signal line SSL may transmit the sensing signal to the first gate electrode GAT1.

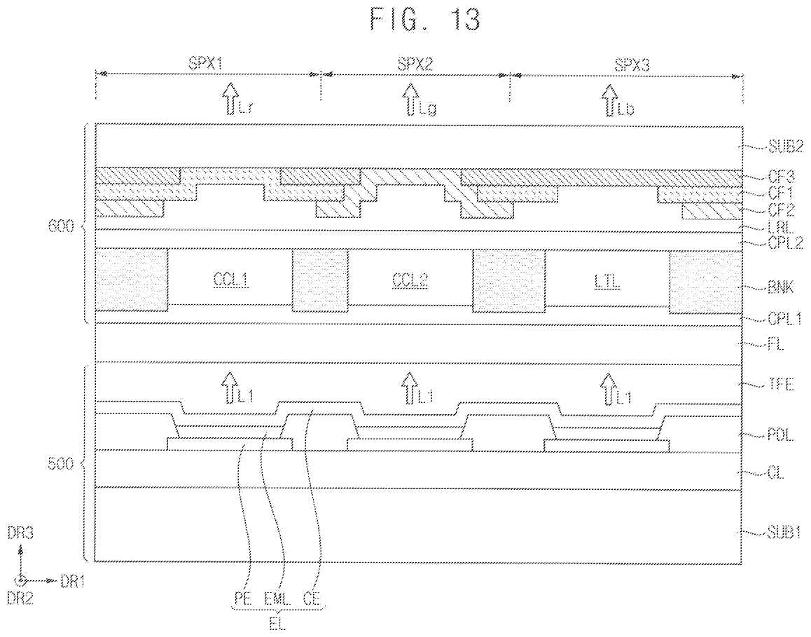

FIG. 12 is a schematic cross-sectional view taken along line IV-IV′ of FIG. 4. However, the same reference numerals are used for the same components as in FIGS. 9, 10 and 11, and overlapping descriptions of the same components will be omitted.

Referring to FIGS. 4 and 12, the second active pattern ACT2 of the active layer 200 may be disposed on the buffer layer 150. The second gate electrode GAT2 may be disposed on the second active pattern ACT2. The second gate electrode GAT2 may define the second channel region CA2 in an area overlapping the second active pattern ACT2. A portion (e.g., the first portion GAT21 shown in FIG. 7) of the second gate electrode GAT2 overlapping the second active pattern ACT2 and the second active pattern ACT2 may constitute a second transistor (e.g., the second transistor T2 shown in FIG. 2)

The third transmission electrode TE3 of the third conductive layer 400 may be connected to the second active pattern ACT2 through a contact hole formed by removing a portion of the second insulating layer 350. Accordingly, a portion of the third transmission electrode TE3 overlapping the second active pattern ACT2 may serve as a drain electrode.

The gate signal line GSL of the third conductive layer 400 may be connected to the second gate electrode GAT2 through a second contact hole CNT2 formed by removing a portion of the second insulating layer 350. For example, the gate signal line GSL may be electrically connected to the second gate electrode GAT2 through the second contact hole CNT2. Accordingly, the gate signal line GSL may transmit the gate signal to the second gate electrode GAT2.

Referring to FIGS. 1 to 12, the display device 1000 according to an embodiment may include a sub-pixel (e.g., the first sub-pixel SPX1 of the first pixel PX1) including a transistor (e.g., the third transistor T3 shown in FIG. 2) and a light emitting element (e.g., the light emitting element EL shown in FIG. 2) disposed on the transistor, the source line SRL extending in the first direction DR1 and connected to the transistor to transmit the initialization voltage to the transistor, and a symmetric sub-pixel (e.g., the first sub-pixel SPX1 of the second pixel PX2) adjacent to the sub-pixel in the second direction DR2 and symmetrical to the sub-pixel with respect to the imaginary symmetric line SL passing through the center of the source line SRL. Accordingly, the capacity of the storage capacitor CST including the first electrode CE1 and the second electrode CE2 may increase. Since the sub-pixel and the symmetric sub-pixel share the source line SRL, a space where lines may be disposed may be additionally allocated. Accordingly, the display quality of the display device 1000 may be improved.

FIG. 13 is a schematic cross-sectional view illustrating a display device according to another embodiment.

Referring to FIG. 13, the display device may include an array substrate 500, a filling layer FL, and a color conversion substrate 600. Here, the array substrate 500 may include a first substrate SUB1, a circuit layer CL, a pixel defining layer PDL, a light emitting element EL, and an encapsulation structure TFE. The color conversion substrate 600 may include a first capping layer CPL1, a bank layer BNK, first and second color conversion layers CCL1 and CCL2, a light transmission layer LTL, a second capping layer CPL2, a low refractive index layer LRL, first, second, and third color filter layers CF1, CF2, and CF3, and a second substrate SUB2. However, the display device described with reference to FIG. 13 may be substantially the same as or similar to the display device 1000 described with reference to FIG. 3 except that the display device has a structure including two substrates. Hereinafter, overlapping descriptions will be omitted.

The components of the array substrate 500 may be the same as the components (i.e., the substrate SUB, the circuit layer CL, the pixel defining layer PDL, the light emitting element EL, and the encapsulation structure TFE) of the display device 1000 of FIG. 3. Hereinafter, only the color conversion substrate 600 will be described.

The second substrate SUB2 may be formed of a transparent resin substrate. For example, the second substrate SUB2 may include an insulating material such as glass or plastic. In other embodiments, the second substrate SUB2 may include an organic polymer material such as polycarbonate, polyethylene, polypropylene, and the like, or a combination thereof.

The first, second, and third color filter layers CF1, CF2, and CF3 may be disposed under the second substrate SUB2. Specifically, the first, second, and third color filter layers CF1, CF2, and CF3 may be disposed in an order of the third color filter layer CF3, the first color filter layer CF1, and the second color filter layer CF2 under the second substrate SUB2.

The low refractive index layer LRL may be disposed under the first, second, and third color filter layers CF1, CF2, and CF3. The low refractive index layer LRL may cover the first, second, and third color filter layers CF1, CF2, and CF3. The low refractive index layer LRL may have a relatively low refractive index. For example, the low refractive index layer LRL may include an organic material.

The second capping layer CPL2 may be disposed under the low refractive index layer LRL. For example, the second capping layer CPL2 may include a silicon compound. A bank layer BNK may be disposed under the second capping layer CPL2. The bank layer BNK may surround the first color conversion layer CCL1, the second color conversion layer CCL2, and the light transmission layer LTL. For example, the bank layer BNK may include an organic material.

The first color conversion layer CCL1, the second color conversion layer CCL2, and the light transmission layer LTL may be disposed under the second capping layer CPL2. The first capping layer CPL1 may be disposed under the bank layer BNK, the first color conversion layer CCL1, the second color conversion layer CCL2, and the light transmission layer LTL. The first capping layer CPL1 may cover the bank layer BNK, the first color conversion layer CCL1, the second color conversion layer CCL2, and the light transmission layer LTL. For example, the first capping layer CPL1 may include a silicon compound.

The filling layer FL may be disposed between the array substrate 500 and the color conversion substrate 600. The filling layer FL may fill between the array substrate 500 and the color conversion substrate 600. The filling layer FL may include a material capable of transmitting light. For example, the filling layer FL may include an organic material. In another embodiment, the filling layer FL may be omitted.

For example, in FIG. 3, the display device 1000 of the disclosure has a single substrate structure as an example, but the display device described with reference to FIG. 13 may be a structure having two substrates (e.g., the first substrate SUB1 and the second substrate SUB2).

The disclosure can be applied to various devices that include a display device. For example, the disclosure can be applied to high-resolution smartphones, mobile phones, smart pads, smart watches, tablet PCs, in-vehicle navigation systems, televisions, computer monitors, notebook computers, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications are intended to be included within the scope of the disclosure. Therefore, it is to be understood that the foregoing is illustrative of various embodiments and is not to be construed as limited to the specific embodiments disclosed, and that modifications to the disclosed embodiments, as well as other embodiments, are intended to be included within the scope of the disclosure.

What is claimed is:

1. A display device comprising:
a substrate;
a sub-pixel including:
a transistor including an active pattern disposed on the substrate and a gate electrode disposed on the active pattern and defining a channel area in an area overlapping the active pattern; and
a light emitting element disposed on the transistor;
a sensing signal line disposed on the gate electrode to overlap the channel area and that transmits a sensing signal to the gate electrode;
a source line extending in a first direction, electrically connected to the active pattern, and that transmits an initialization voltage to the active pattern; and
a symmetric sub-pixel having a same structure as the sub-pixel, adjacent to the sub-pixel in a second direction intersecting the first direction, and symmetrical to the sub-pixel with respect to an imaginary symmetric line passing through a center of the source line.

2. The display device of claim 1, wherein the sub-pixel and the symmetric sub-pixel share the source line.

3. The display device of claim 1, wherein an entirety of the gate electrode overlaps the sensing signal line.

4. The display device of claim 1, wherein each of the gate electrode and the sensing signal line extends in the first direction.

5. The display device of claim 1, wherein
each of the gate electrode and the sensing signal line extends in the first direction, and
the active pattern extends in the second direction.

6. The display device of claim 1, further comprising:
an insulating layer disposed between the gate electrode and the sensing signal line,
wherein the sensing signal line is electrically connected to the gate electrode through a contact hole formed by removing a portion of the insulating layer.

7. The display device of claim 6, wherein the contact hole is spaced apart from the active pattern in a plan view.

8. The display device of claim 1, wherein the source line and the sensing signal line are disposed on a same layer.

9. The display device of claim 1, wherein the source line and the sensing signal line extend in a same direction.

10. The display device of claim 1, further comprising:
an insulating layer disposed between the gate electrode and the sensing signal line,
wherein the source line is electrically connected to the active pattern through a contact hole formed by removing a portion of the insulating layer.

11. The display device of claim 1, wherein
the sub-pixel further includes a storage capacitor including a first electrode and a second electrode,
the first electrode and the gate electrode are disposed on a same layer, and
the second electrode and the sensing signal line are disposed on a same layer.

12. The display device of claim 1, wherein a length of the sensing signal line in the first direction is greater than a length of the gate electrode in the first direction.

13. The display device of claim 1, wherein the gate electrode and the sensing signal line include a same conductive material.

14. The display device of claim 1, wherein
the active pattern includes:
a first portion; and
a second portion having a planer shape symmetrical to the first portion with respect to the imaginary symmetric line, and
the transistor includes the second portion of the active pattern.

15. The display device of claim 1, further comprising:
a data line disposed between the substrate and the active pattern, wherein
the data line extends in the second direction, and
the gate electrode extends in the first direction.

16. The display device of claim 1, wherein each of the sub-pixel and the symmetric sub-pixel is one of a red sub-pixel, a green sub-pixel, and a blue sub-pixel.

17. A display device comprising:
a substrate;
a sub-pixel including:
a transistor disposed on the substrate; and
a light emitting element disposed on the transistor;
a source line extending in a first direction, electrically connected to the transistor, and that transmits an initialization voltage to the transistor; and
a symmetric sub-pixel having a same structure as the sub-pixel, adjacent to the sub-pixel in a second direction intersecting the first direction, and symmetrical to the sub-pixel with respect to an imaginary symmetric line passing through a center of the source line.

18. The display device of claim 17, wherein the sub-pixel and the symmetric sub-pixel share the source line.

19. The display device of claim 17, wherein the transistor includes:
an active pattern disposed on the substrate; and
a gate electrode defining a channel area in an area overlapping the active pattern.

20. The display device of claim 19, wherein
the sub-pixel further includes a storage capacitor including a first electrode and second electrode,
the first electrode and the gate electrode are disposed on a same layer, and
the second electrode and the source line are disposed on a same layer.
